(19) United States
(12) Patent Application Publication
(10) Pub. No.: US 2025/0172637 A1
(43) Pub. Date: May 29, 2025

(54) SIGNAL PROCESSING CIRCUIT AND SENSOR UNIT

(71) Applicant: TDK Corporation, Tokyo (JP)

(72) Inventor: Keita MIYACHI, Tokyo (JP)

(73) Assignee: TDK Corporation, Tokyo (JP)

(21) Appl. No.: 18/954,622

(22) Filed: Nov. 21, 2024

(30) Foreign Application Priority Data
Nov. 27, 2023 (JP) 2023-199859

(51) Int. Cl. G01R 33/00; G01R 33/09; H10N 50/10

(52) U.S. Cl. CPC G01R 33/0017; G01R 33/093; H10N 50/10

(57) ABSTRACT

A signal processing circuit processes a detection signal, output from a sensor, and including a direct-current component and an alternating-current component and includes a low-pass filter that extracts the direct-current component from the detection signal and a high-pass filter that extracts the alternating-current component from the detection signal.

### CROSS-REFERENCE TO RELATED APPLICATION

The present application is based upon and claims the benefit of priority from Japanese Patent Application No. 2023-199859, filed on Nov. 27, 2023, the entire contents of which are hereby incorporated by reference.

The present disclosure relates to a signal processing circuit and a sensor unit.

### BACKGROUND

To improve accuracy of detection by a sensor, various signal processing may be performed on a detection signal output from the sensor. For example, Patent Publication JP-A-2016-180727 discloses a signal processing circuit that performs amplification processing or the like on an output signal from a magnetic sensor to allow detection accuracy to be improved.

### SUMMARY

A signal processing circuit according to an aspect of the present disclosure provides a signal processing circuit that processes a detection signal, output from a sensor, and including a direct-current component and an alternating-current component and includes: a low-pass filter that extracts the direct-current component from the detection signal; and a high-pass filter that extracts the alternating-current component from the detection signal.

A sensor unit according to the aspect of the present disclosure includes a sensor and a signal processing circuit formed integrally with the sensor.

### BRIEF DESCRIPTION OF THE DRAWINGS

The accompanying drawings are included to provide a further understanding of the disclosure and are incorporated in and constitute a part of this specification. The drawings illustrate example embodiments and, together with the specification, serve to explain the principles of the technology.

FIG. 1 is a block diagram illustrating a schematic configuration of a sensor unit 100 according to the present example embodiment;

FIG. 2 is a schematic perspective view of the sensor unit 100 according to the present example embodiment;

FIG. 3 is a circuit diagram illustrating a schematic configuration of a magnetic detection unit 10 according to the present example embodiment;

FIG. 4 is a perspective view illustrating a schematic configuration of a magnetoresistance effect element 14 according to the present example embodiment;

FIG. 5 is a circuit diagram illustrating the schematic configuration of the magnetic detection unit 10 according to the present example embodiment;

FIG. 6 is a functional block diagram illustrating a configuration of the sensor unit 100 according to the present example embodiment;

FIG. 7 is a diagram illustrating an example of a signal waveform according to the present example embodiment;

FIG. 8A is a diagram illustrating a frequency characteristic of a signal according to the present example embodiment;

FIG. 8B is a diagram illustrating the frequency characteristic of the signal according to the present example embodiment;

FIG. 8C is a diagram illustrating the frequency characteristic of the signal according to the present example embodiment;

FIG. 9 is a functional block diagram illustrating the configuration of the sensor unit 100 according to the present example embodiment;

FIG. 10 is a diagram illustrating the frequency characteristic of the signal according to the present example embodiment;

FIG. 11 is a functional block diagram illustrating the configuration of the sensor unit 100 according to the present example embodiment;

FIG. 12 is a diagram schematically illustrating an example of a characteristic of the magnetic detection unit 10 according to the present example embodiment; and

FIG. 13 is a diagram schematically illustrating an example of the characteristic of the magnetic detection unit 10 according to the present example embodiment.

### DETAILED DESCRIPTION

In the following, some example embodiments and modification examples of the technology are described in detail with reference to the accompanying drawings. Note that the following description is directed to illustrative examples of the disclosure and not to be construed as limiting the technology. Factors including, without limitation, numerical values, shapes, materials, components, positions of the components, and how the components are coupled to each other are illustrative only and not to be construed as limiting the technology. Further, elements in the following example embodiments which are not recited in a most-generic independent claim of the disclosure are optional and may be provided on an as-needed basis. The drawings are schematic and are not intended to be drawn to scale. Like elements are denoted with the same reference numerals to avoid redundant descriptions.

Depending on a detection signal output from a sensor and input to a signal processing circuit or signal processing performed on the detection signal, power consumption, which is power consumed in the signal processing, may possibly be increased. For example, in a magnetic sensor, when a sensitivity of the sensor is low, to accurately sense detected magnetism, amplification processing is performed on the detection signal. In signal processing such as the amplification processing, depending on a signal to be subjected to the signal processing, the power consumption may possibly be increased.

The present disclosure has been achieved in view of such circumstances, and an object of the present disclosure is to provide a signal processing circuit capable of reducing power consumption.

Referring to the accompanying drawings, a description will be given below of one example embodiment (hereinafter referred to also as the “present embodiment”) of the present disclosure. In the drawings accompanying the present specification, for the convenience of ease of illustration and understanding, a scale, an aspect ratio, and the like may appropriately be changed and exaggerated from those of an actual substance.

In the following, as an example of a signal processing circuit according to the example embodiment of the present disclosure, a signal processing circuit that processes a signal detected by a magnetic sensor will be described. However, the signal processing circuit according to the example embodiment of the present disclosure may also be used for signal processing of a signal other than the signal detected by the magnetic sensor. The signal processing circuit according to the present example embodiment may also be used for signal processing of, e.g., a signal detected by another sensor other than the magnetic sensor.

In the following, in each of the drawings, an X-axis, a Y-axis, and a Z-axis may be illustrated. The X-axis, the Y-axis, and the Z-axis form right-handed three-dimensional orthogonal coordinates. Hereinbelow, a direction of an arrow of the X-axis may be referred to as a +X-axis direction, while a direction opposite to the direction of the arrow may be referred to as a −X-axis direction. The same applies also to the other axes. Note that, a +Z-direction and a −Z-direction may be referred to as an “upper side” or “upside” and a “lower side” or “underside”, respectively. A Z-axis direction may be referred to also as the “stacking direction”. Furthermore, planes orthogonal to the X-axis, the Y-axis, and the Z-axis may be referred to also as a YZ-plane, a ZX-plane, and an XY-plane, respectively. Note that these directions and the like are used for the sake of convenience to describe relative positional relationships. Therefore, these directions and the like are not intended to define absolute positional relationships.

Terms and/or numerical values that mean shapes and/or geometric conditions are not necessarily limited to strict definitions thereof, and may also be construed to include a range to a degree that similar functions may be expected. For example, terms such as “parallel” and/or “orthogonal” correspond to the terms mentioned above. Values such as “values of length” and/or “values of angle” correspond to the numeric values mentioned above.

In a case where a given component is expressed as being “on”, “under”, “on an upper side of”, “on a lower side of”, “above”, or “below” another component, the case may also include an aspect in which the given component is in direct contact with the other component and an aspect in which a different component is included between the given component and the other component. In other words, the aspect in which the different component is included between the given component and the other component may also be expressed as the given component and the other component being in indirect contact with each other. The expression “on”, “upper side”, or “above” is replaceable with the expression “under”, “lower side”, or “below”. In other words, an up-down direction may also be reversed. The same applies also to a left-right direction.

In the following, when identical portions and/or portions having similar functions are designated by identical reference signs or like reference signs, a repeated description may be omitted. The ratio of dimensions in the drawings may differ from an actual ratio. Illustration of some of components in an embodiment may be omitted from the drawings.

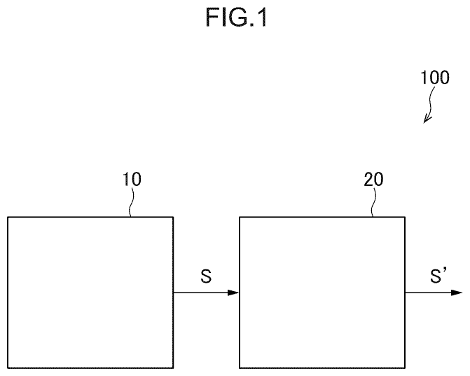

FIG. 1 is a block diagram illustrating a schematic configuration of a sensor unit 100 according to the present example embodiment. As illustrated in FIG. 1, the sensor unit 100 according to the present example embodiment includes a magnetic detection unit 10 (referred to also as the “magnetic sensor” in the present example embodiment) and a signal processing circuit 20. As a result of application of a magnetic field to the magnetic detection unit 10, the magnetic detection unit 10 outputs a magnetic signal S. The signal processing circuit 20 processes the magnetic signal S input thereto from the magnetic detection unit 10. The signal processing circuit 20 performs signal processing on the magnetic signal S and outputs a signal S′.

In the present example embodiment, the magnetic detection unit 10 may also be, e.g., a TMR (Tunnel magnetoresistance effect) element. The magnetic detection unit 10 is not limited to the TMR element, and may also be a GMR (Giant magnetoresistance effect) element, an AMR (Anisotropic magnetoresistance effect) element, a Hall element, or another type of magnetic detection element.

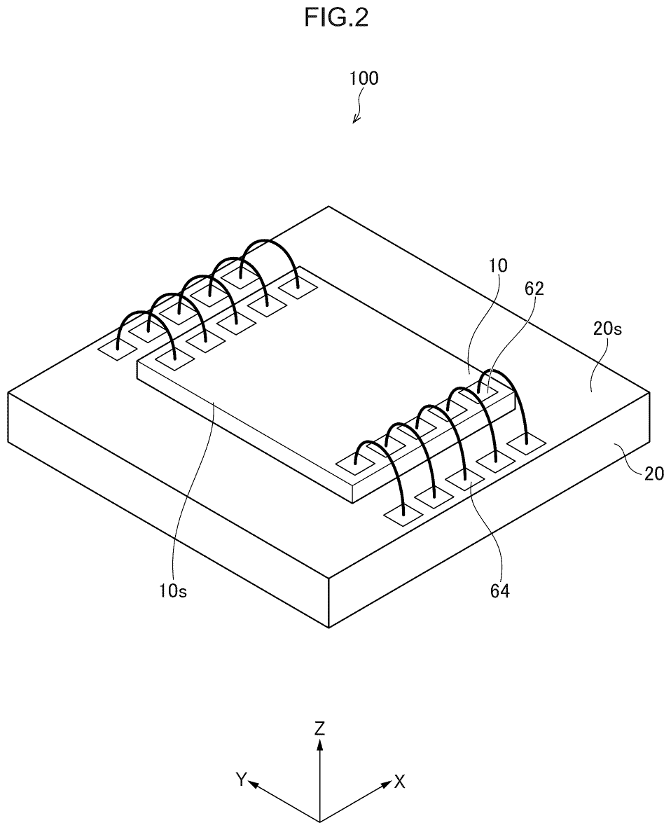

FIG. 2 is a schematic perspective view of the sensor unit 100. As illustrated in FIG. 2, the magnetic detection unit 10 may be formed on the signal processing circuit 20 (+Z-direction). On an upper surface 10s of the magnetic detection unit 10, a terminal group 62 may be provided while, on an upper surface 20s of the signal processing circuit 20, a terminal group 64 may be provided. The terminal group 62 of the magnetic detection unit 10 and the terminal group 64 of the signal processing circuit 20 may be connected to each other via, e.g., a plurality of bonding wires 50. The magnetic detection unit 10 may also be configured to detect, e.g., an external magnetic field.

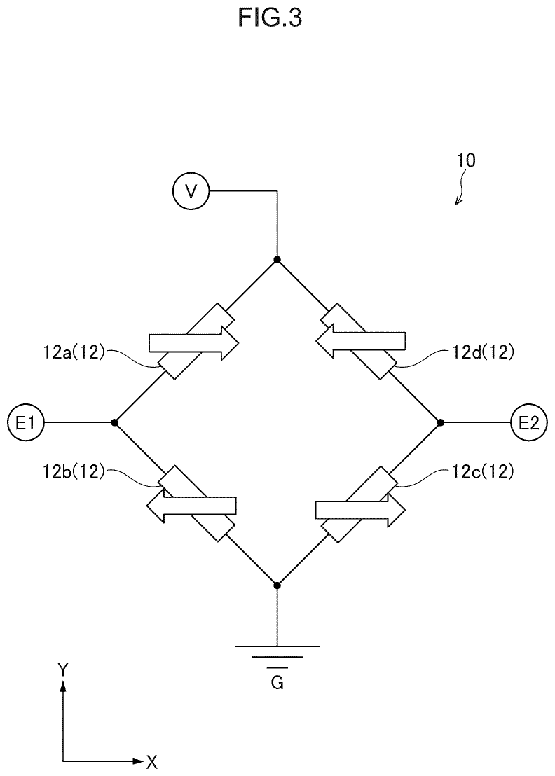

FIG. 3 is a circuit diagram illustrating a schematic configuration of the magnetic detection unit 10. As illustrated in FIG. 3, the magnetic detection unit 10 has, e.g., one or a plurality of element units 12. In the example illustrated in FIG. 3, the magnetic detection unit 10 may have a first element unit 12a, a second element unit 12b, a third element unit 12c, and a fourth element unit 12d. The plurality of element units 12 of the magnetic detection unit 10 may also form a Wheatstone bridge circuit.

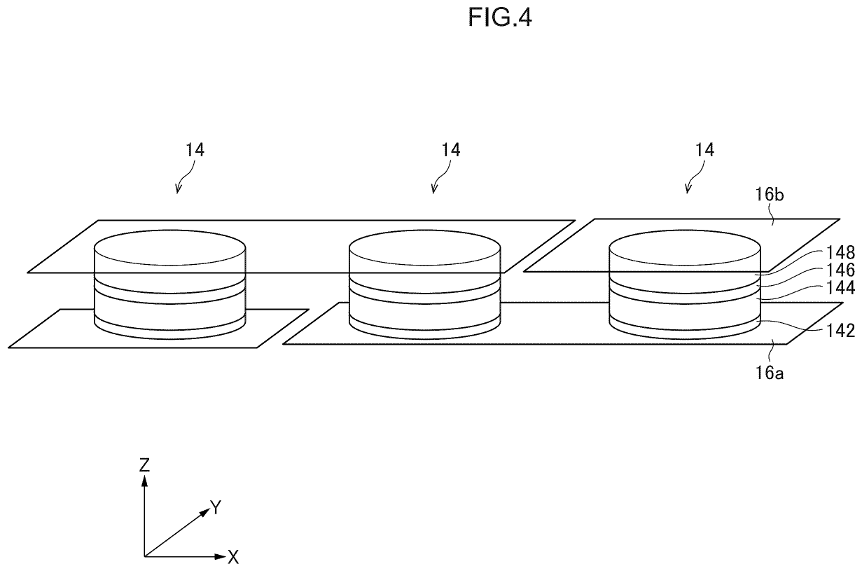

FIG. 4 is a perspective view illustrating a schematic configuration of a magnetoresistance effect element 14 (hereinafter referred to also as the “MR element”) included in each of the element units 12. The element unit 12 may include, e.g., a plurality of the magnetoresistance effect elements 14 connected in series, and each of the plurality of magnetoresistance effect elements 14 may also be, e.g., a spin-valve-type magnetoresistance effect element. As illustrated in FIG. 4, in the present example embodiment, each of the magnetoresistance effect elements 14 may also have, e.g., a substantially ellipsoidal shape. In the present example embodiment, to the element units 12, the magnetoresistance effect elements 14 may also be connected via a plurality of connection layers 16.

As illustrated in FIG. 4, e.g., a first connection layer 16a among the plurality of connection layers 16 may be in contact with lower surfaces of the two MR elements 14 which may be adjacent in a circuit configuration to electrically connect these MR elements 14. Meanwhile, a second connection layer 16b may be in contact with upper surfaces of the adjacent MR elements 14 to electrically connect these MR elements 14.

As also illustrated in FIG. 4, each of the MR elements 14 may have an antiferromagnetic layer 142, a magnetization fixed layer 144, a gap layer 146, and a free layer 148. As illustrated in FIG. 4, the antiferromagnetic layer 142 may be electrically connected to the first connection layer 16a, while the free layer 148 may be electrically connected to the second connection layer 16b. The antiferromagnetic layer 142 may contain an antiferromagnetic material. The antiferromagnetic layer 142 may also cause exchange coupling to the magnetization fixed layer 144 to fix a magnetization direction of the magnetization fixed layer 144.

The spin-valve-type MR element 14 is, e.g., a TMR element or a GMR element. When the MR element is the TMR element, the gap layer 146 may be, e.g., a tunnel barrier layer. When the MR element is the GMR element, the gap layer 146 may be, e.g., a non-magnetic conductive layer. Note that an arrangement of the antiferromagnetic layer 142, the magnetization fixed layer 144, the gap layer 146, and the free layer 148 which are included in the MR element 14 is not limited to that in an example illustrated in FIG. 4. For example, the antiferromagnetic layer 142, the magnetization fixed layer 144, the gap layer 146, and the free layer 148 may also be stacked in the Z-direction in reverse order of that in the example illustrated in FIG. 4.

In the spin-valve-type magnetoresistance effect element 14, a resistance value changes according to an angle formed by a magnetization direction of the free layer 148 with respect to the magnetization direction of the magnetization fixed layer 144 and, when the angle is 0°, the resistance value may be minimized and, when the angle is 180°, the resistance value may be maximized.

For example, as has been described above with reference to FIG. 3, the magnetic detection unit 10 includes the first element unit 12a, the second element unit 12b, the third element unit 12c, and the fourth element unit 12d which are the plurality of element units 12, and the first element unit 12a, the second element unit 12b, the third element unit 12c, and the fourth element unit 12d may also form a full-bridge Wheatstone bridge circuit. The Wheatstone bridge circuit illustrated in FIG. 3 may include a power source port V, a ground port G, and output ports E1 and E2. To the power source port V, a voltage of a predetermined magnitude may be applied, while the ground port G may be connected to the ground. It may be possible that one end of the first element unit 12a is connected to the power source port V, while another end of the first element unit 12a is connected to the output port E1. It may also be possible that one end of the second element unit 12b is connected to the output port E1, while another end of the second element unit 12b is connected to the ground port G. Likewise, it may also be possible that one end of the third element unit 12c is connected to the ground port G, while another end of the third element unit 12c is connected to the output port E2, and it may also be possible that one end of the fourth element unit 12d is connected to the output port E2, while another end of the fourth element unit 12d is connected to the power source port V.

In the present example embodiment, e.g., the magnetization direction of the magnetization fixed layer 144 of each of the magnetoresistance effect elements 14 may be fixed to a direction parallel to the X-axis. As indicated by an arrow in FIG. 3, e.g., the magnetization direction of the magnetization fixed layer 144 of the magnetoresistance effect element 14 of each of the first element unit 12a and the third element unit 12c may be the “+X-direction”, while the magnetization direction of the magnetization fixed layer 144 of the magnetoresistance effect element 14 of each of the second element unit 12b and the fourth element unit 12d may be the “−X-direction”. The magnetization direction of the magnetization fixed layer 144 of the magnetoresistance effect element 14 of each of the first to fourth element units 12a to 12d may be parallel to a short diameter direction or short side direction of the magnetoresistance effect element 14 having a substantially ellipsoidal shape or a substantially rectangular shape in plan view and, accordingly, a sensitivity axis of the magnetoresistance effect element 14 of each of the first to fourth element units 12a to 12d may be parallel to the X-axis.

Meanwhile, in the present example embodiment, the magnetization direction of the free layer 148 of each of the magnetoresistance effect elements 14 in an initial state, which is a state where a magnetic field to be detected by the magnetic detection unit 10 is not applied, may be parallel to the Y-axis. In an aspect illustrated by way of example in FIG. 3, a direction of an axis of easy magnetization of the free layer 148 of the magnetoresistance effect element 14 of each of the first element unit 12a and the fourth element unit 12d may be the “−Y-direction”, while a direction of the axis of easy magnetization of the free layer 148 of the magnetoresistance effect element 14 of each of the second element unit 12b and the third element unit 12c may be the “+Y-direction”. In the present example embodiment, e.g., the direction of the axis of easy magnetization of the free layer 148 of the magnetoresistance effect element 14 of each of the first to fourth element units 12a to 12d may be parallel to a long diameter direction of the magnetoresistance effect element 14 having the substantially ellipsoidal shape in plan view.

In the present example embodiment, in the magnetic detection unit 10 illustrated in FIG. 3, with application of the magnetic field to the magnetoresistance effect element 14 of each of the first to fourth element units 12a to 12d, a potential difference between the output ports E1 and E2 may change, and a differential detector unit not shown may output, to a signal processing unit 20, the signal S corresponding to the potential difference between the output ports E1 and E2 as a signal representing a magnetic field intensity.

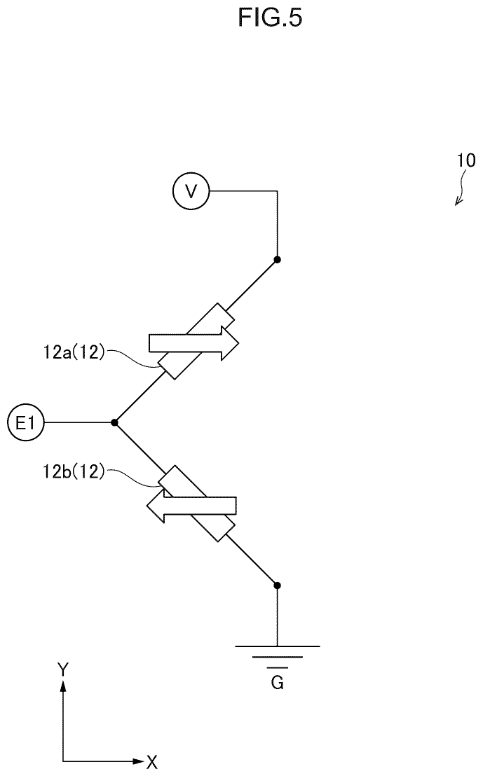

Note that, as illustrated in FIG. 5, the magnetic detection unit 10 may also form a half-bridge Wheatstone bridge circuit. At this time, as illustrated in FIG. 5, the magnetic detection unit 10 may have the two element units (the first element unit 12a and the second element unit 12b). As illustrated in FIG. 5, it may also be possible that the one end of the first element unit 12a is connected to the power source port V, while the other end of the first element unit 12a is connected to the output port E1, and that the one end of the second element unit 12b is connected to the output port E1, while the other end of the second element unit 12b is connected to the ground port G.

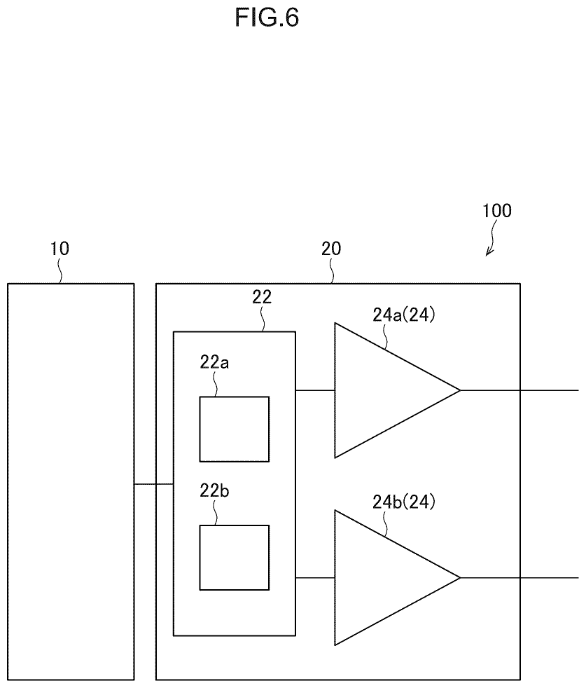

The following will describe the signal processing unit 20 of the sensor unit 100, which is an example of the signal processing circuit according to the present example embodiment. FIG. 6 is a functional block diagram illustrating a configuration of the sensor unit 100 according to the present example embodiment. The signal processing unit 20 according to the present example embodiment is a signal processing circuit that processes the detection signal S output from the magnetic detection unit 10 serving as the sensor. As will be described below, in the present example embodiment, the detection signal S output from the magnetic detection unit 10 includes a direct-current component and an alternating-current component. The signal processing unit 20 includes a low-pass filter 22a that extracts the direct-current component from the detection signal S and a high-pass filter 22b that extracts the alternating-current component from the detection signal S. Therefore, in the present example embodiment, a separation circuit 22 of the signal processing circuit 20 includes the low-pass filter 22a and the high-pass filter 22b. The signal processing circuit 20 may also further include an amplification circuit 24. A description will be given later of the amplification circuit 24.

Note that, by way of example, FIG. 6 illustrates a case where signals for an X-component, a Y-component, and a Z-component (which are respectively Sx, Sy, and Sz described above) may be input from the magnetic detection unit 10 to the signal processing circuit 20 and, in FIG. 6, the magnetic detection unit 10 may include a first magnetic detection unit 10a, a second magnetic detection unit 10b, and a third magnetic detection unit 10c, which are mentioned above.

Also, in the present example embodiment, the direct-current component of the detection signal may also include a component with a frequency other than a component with a zero frequency. For example, the direct-current component of the detection signal may also include, in addition to the component with the zero frequency, a component in a predetermined frequency range in which each frequency is 1 or more. For example, the direct-current component of the detection signal in the present example embodiment may also include a component with a frequency of not less than zero hertz (Hz) and not more than 100 hertz. At this time, the alternating-current component of the detection signal in the present example embodiment may also include a component with a frequency exceeding 100 hertz. Alternatively, the direct-current component of the detection signal in the present example embodiment may also include a component with a frequency of not less than zero hertz and not more than 1000 hertz and, at this time, the alternating-current component of the detection signal in the present example embodiment may also include a component with a frequency exceeding 1000 hertz. In the present specification, the present example embodiment will be described hereinbelow on the assumption that the direct-current component of the detection signal includes a component with a frequency ranging from zero hertz (Hz) to a predetermined frequency of not less than 100 hertz, while the alternating-current component of the detection signal includes a component in a frequency band larger than a frequency band of the direct-current component.

As a result of conducting study, the present inventors have found that, depending on a detection signal output from a sensor and input to a signal processing circuit or signal processing performed on the detection signal, power consumption, which is power consumed in the signal processing, may be increased. For example, it has been found that, in a case where a magnetic sensor is used as the sensor and the signal processing is performed on the detection signal output from the magnetic sensor, an alternating-current magnetic field (AC magnetic field) is superimposed on a magnetic field signal of a direct-current magnetic field (DC magnetic field) and, in a case where each of the alternating-current component (AC component) of the magnetic field signal and the direct-current component (DC component) of the magnetic field signal is input to a magnetic sensor unit, when the signal processing is performed on the magnetic field signal in which the AC component is superimposed on the DC component, power consumption required for the signal processing may be increased.

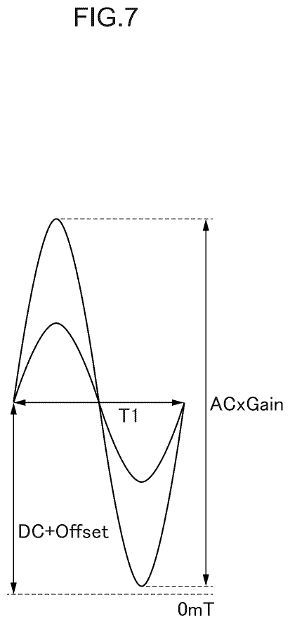

FIG. 7 illustrates an example of a signal waveform of the magnetic field signal to be processed in the magnetic sensor unit in this case. As illustrated in FIG. 7, the magnetic field signal in which the AC component with a period T1 is superimposed on the DC component is input. For example, when the amplification processing was performed on the magnetic field signal in which the AC component was superimposed on the DC component, required power consumption was occasionally not less than three times or more the power consumption when the amplification processing is performed only on the DC component.

For example, in an information processor, an information device, or the like that uses a sensor to perform information transmission or the like, by superimposing not only the DC component, but also the AC component, a larger amount of information can be transmitted. However, expansion of a frequency range of a signal may result in increased power consumption. For example, particularly in a small-sized mobile information device or the like, it may be preferred not to increase power consumption.

In a mobile information device or the like, in order to increase an amount of information, superimposition of the AC component on the DC component or the like has been performed in recent years, which may increase output signals from various sensors provided in the information device to a signal processing circuit. In addition, with increasing sophistication of performance and functions of the information device, a larger number of sensors may be mounted therein, which may result in increased amounts of information from the larger number of sensors. However, particularly in a mobile information device, it may be preferred to suppress power consumption from a viewpoint of battery drain, and it may be preferred to suppress power consumption also in a circuit that performs signal processing on the output signals from the sensors. For example, in a mobile terminal, a magnetic sensor such as a compass is mounted, and it may be required to reduce power consumption particularly in the compass.

For example, when the detection signal input to the signal processing circuit is to be amplified, as the amplification circuit, a telescopic amplification circuit in which power consumption can relatively be reduced compared to that in a folded-cascode amplification circuit may be used. However, in the telescopic amplification circuit, due to the limited number of transistors that can be used therein, an input voltage cannot be increased and, accordingly, it may be difficult to increase the detection signals input thereto from the sensors. Therefore, it may be conceivable that, particularly in a mobile information device or the like, a signal processing circuit capable of suppressing increased power consumption, while increasing the output signals from the sensors, may be desired.

Thus, the present inventors have succeeded in reducing power consumption in the signal processing of the detection signal S by using the separation circuit 22 to perform separation processing on the magnetic field signal (an example of the detection signal S), i.e., by using the low-pass filter 22a (LP) to extract the direct-current component, using the high-pass filter 22b (HP) to extract the alternating-current component, and separating the detected magnetic field signal, and have successfully arrived at the signal processing circuit 20 according to the example embodiment of the present disclosure.

In other words, as has been described above with reference to FIG. 6, the signal processing circuit 20 of the sensor unit 100 according to the present example embodiment includes the low-pass filter 22a and the high-pass filter 22b. In the signal processing unit 20, from the detection signal S output from the magnetic detection unit 10 and including the direct-current component and the alternating-current component, the direct-current component is extracted using the low-pass filter 22a and the alternating-current component is extracted using the high-pass filter 22b.

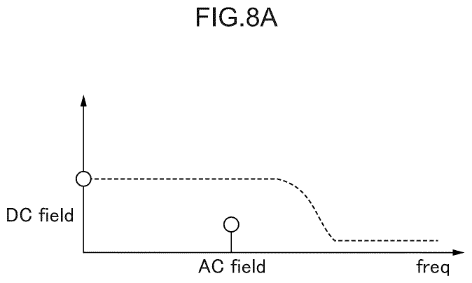

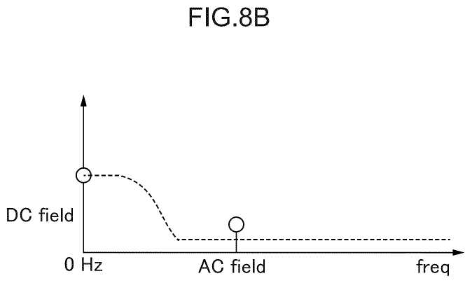

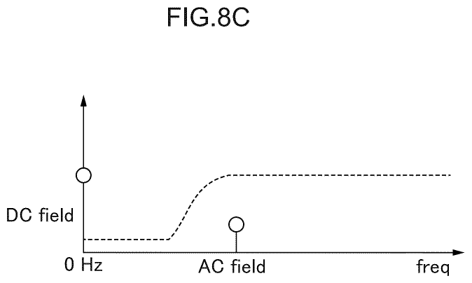

FIG. 8A schematically illustrates a frequency characteristic of an input signal in which an AC component is superimposed on a DC component. FIG. 8B illustrates a frequency characteristic of the DC component after the separation, while FIG. 8C illustrates a frequency characteristic of the AC component after the separation. As illustrated in FIG. 8A, FIG. 8B, and FIG. 8C, in the signal processing circuit 20 according to the present example embodiment, from a signal (FIG. 8A) in which a relatively large amplitude is recognized up to a relatively high frequency range (e.g., several hundreds to several thousands of hertz), a direct-current component (FIG. 8B) is extracted by the low-pass filter 22a (e.g., a band of not more than 100 hertz in the present example embodiment) and an alternating-current component (FIG. 8C) is extracted by the high-pass filter 22b (e.g., a band exceeding 100 hertz in the present example embodiment).

On each of the direct-current component and the alternating-current component that have been extracted, e.g., signal processing in a subsequent step is performed. As illustrated in FIG. 6, the signal processing circuit 20 may include, e.g., a first amplification circuit 24a (referred to also as the “first signal processing unit” in the present example embodiment) and a second amplification circuit 24b (referred to also as the “second signal processing unit” in the present example embodiment), and it may also be possible that direct-current component after the separation is amplified by the first amplification circuit 24a (first signal processing in the present example embodiment), while the alternating-current component after the separation is amplified by the second amplification circuit 24b (second signal processing in the present example embodiment). Power consumption in signal processing performed at this time, such as amplification processing, can be reduced compared to that in a case of performing signal processing such as amplification processing on the input signal in which the AC component is superimposed on the DC component without performing the separation thereof.

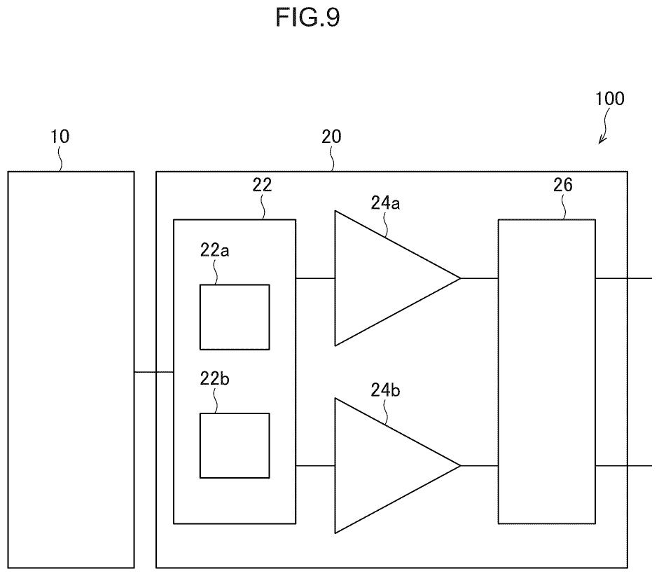

In the signal processing circuit 20 according to the present example embodiment, addition processing may also be performed on the DC component and the AC component of the detection signal S after the separation. As illustrated in FIG. 9, the signal processing circuit 20 according to the present example embodiment may also include an addition circuit (signal addition unit 26), and the direct-current component extracted by the low-pass filter 22a and the alternating-current component extracted by the high-pass filter 22b may also be added up. In the subsequent signal processing performed on a signal resulting from the addition, power consumption can be reduced compared to that in a case where the input signal described above in which the AC component is superimposed on the DC component mentioned above is processed without being separated.

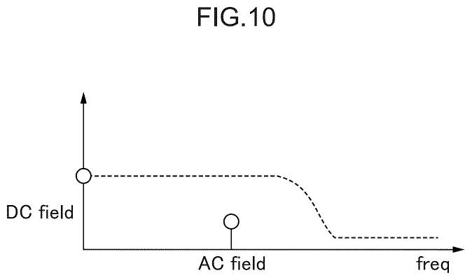

FIG. 10 illustrates a frequency characteristic of the signal obtained by the addition circuit 26 by adding up the DC component (FIG. 8B) and the AC component (FIG. 8C). As illustrated in FIG. 10, the signal resulting from the addition spans respective frequency ranges of the DC component and the AC component, and shows the same frequency characteristic as that of the signal before being separated illustrated in FIG. 8A.

Note that, in FIG. 9, a case where the DC component amplified by the first amplification circuit 24a (i.e., a first output signal on which the first signal processing is performed and which is output from the first signal processing unit) and the AC component amplified by the second amplification circuit 24b (i.e., a second output signal on which the second signal processing is performed and which is output from the second signal processing unit) are added up by the addition circuit 26 is illustrated by way of example. However, in the signal processing circuit 20 according to the present example embodiment, the DC component and the AC component before signal processing, such as amplification, is performed may also be added up. In other words, the DC component output from the low-pass filter 22a and the AC component output from the high-pass filter 22b may also be added up.

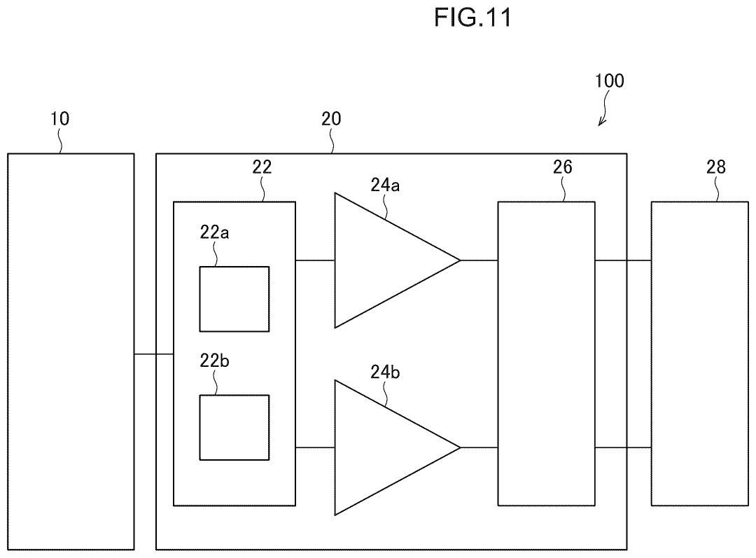

In the signal processing circuit 20 according to the present example embodiment, correction processing may also be performed on the signal resulting from the addition (referred to also as the “addition signal” in the present example embodiment). As illustrated in FIG. 11, the signal processing circuit 20 according to the present example embodiment may also include a correction circuit (signal correction unit 28) that corrects the signal resulting from the addition by the signal addition unit 26, and the following correction processing may also be performed.

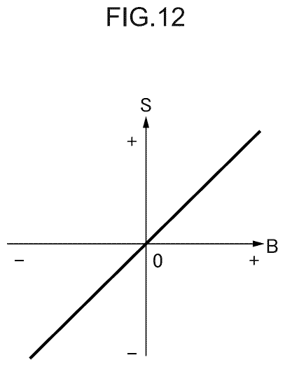

FIG. 12 illustrates an ideal characteristic of the magnetic detection unit 10. FIG. 12 illustrates, e.g., an ideal characteristic of the magnetic detection unit 10 with respect to an X-direction component of the external magnetic field. In FIG. 12, an abscissa axis represents an intensity B of a component of the external magnetic field in a given direction (e.g., the X-direction component), while an ordinate axis represents an X-direction component (Sx) of the detection signal output from the magnetic detection unit 10. In the example illustrated in FIG. 12, when a direction of the X-direction component of the external magnetic field is the +X-direction, the intensity B is represented by a positive value while, when a direction of the X-direction component of the external magnetic field is the −X-direction, the intensity B is represented by a negative value. Also, in the example illustrated in FIG. 12, a value of the detection signal S may be 0 when the intensity B is 0, may be positive when the intensity B has a positive value, may be negative when the intensity B has a negative value, and may increase when the intensity B increases. In other words, as illustrated in FIG. 12, ideally, the detection signal S generated by the magnetic detection unit 10 may be proportional to the intensity B of the external magnetic field.

However, depending on an environment or the like in which the sensor unit 100 is used, the magnetic detection unit 10 may show a characteristic different from the characteristic illustrated by way of example in FIG. 12. For example, a magnetic field in a direction other than the X-axis direction of the external magnetic field or the like may affect the detection signal from the magnetic detection unit 10. At this time, the characteristic with respect to the magnetic field intensity may incur distortion, and a magnitude of an inclination of a magnetic detection characteristic may change according to the intensity B of the external magnetic field.

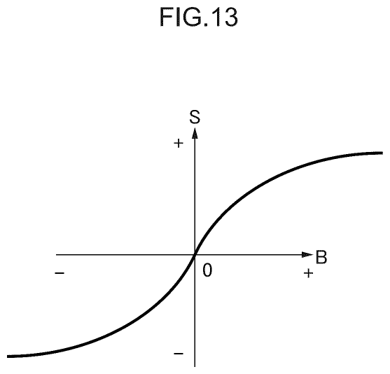

FIG. 13 illustrates a characteristic of the magnetic detection unit when the characteristic is not ideal. As illustrated in FIG. 13, in a case where the characteristic of the magnetic detection unit is not in an ideal state, when, e.g., the intensity B of the external magnetic field increases or decreases, the inclination of the magnetic detection characteristic with respect to the intensity B of the external magnetic field may decrease. Accordingly, the detection signal S may not be proportional to the magnetic field intensity B.

In the present example embodiment, signal correction processing such that, e.g., a characteristic as illustrated by way of example in FIG. 12 is achieved may also be performed. For example, the correction processing may also be performed such that the magnetic field intensity B and the detection signal S have a proportional relationship therebetween.

In the present example embodiment, the correction value applied to the correction processing may also be calculated by using the direct-current component of the detection signal, as described hereinbelow. Note that the calculation of the correction value at this time may also be performed using the direct-current component of the detection signal in, e.g., a test field providing an ideal environment.

As described above, it may be possible that the characteristic of the detection signal from the magnetic detection unit 10 with respect to the magnetic field intensity incurs distortion and an inclination of a change in the detection signal with respect to a magnetic field intensity illustrated by way of example in FIG. 13 changes according to the magnetic field intensity. If only the direct-current component is included in the detection signal, it is conceivable that, e.g., in an ideal environment, the detection signal responding to a change in an external magnetic field intensity is proportional to the change in the external magnetic field intensity to exhibit a linear change illustrated by way of example in FIG. 12. Therefore, in the present example embodiment, by using the correction value calculated by using the direct-current component of the detection signal, it is possible to correct the distortion of the inclination of the change in the detection signal with respect to the magnetic field intensity.

It may also be possible that, e.g., a scale of an amplitude of the AC component of the detected magnetic field signal is relatively smaller than a scale of an amplitude of the DC component thereof (e.g., the scale of the amplitude of the AC component is equal to or less than 1/10 of the scale of the DC component). At this time, in the correction processing performed on the AC component of the detection signal also, by performing the correction processing using the correction value calculated on the basis of the DC component, it is possible to relatively easily bring a characteristic represented by the relationship between the magnetic field intensity B and the detection signal S described above closer to an ideal state compared to that in a case of applying a correction value calculated on the basis of the AC component.

It may also be possible that, e.g., the magnetic signal detected by the magnetic detection unit 10 incurs an offset due to a factor other than the magnetic field to be sensed. For example, when a magnetic field generated by a magnetic generator not shown is to be detected by the magnetic detection unit 10, an offset due to a factor other than the magnetic generator may occur. In this case, it may also be possible that a correction value for correcting the offset is calculated, and correction processing is performed by the signal correction circuit 28.

In the example embodiment described above, in the sensor unit 100 according to the present example embodiment, the magnetic detection unit 10 and the signal processing circuit 20 may be formed as separate bodies and formed by being sealed with a resin or the like or, alternatively, the magnetic detection unit 10 and the signal processing circuit 20 may also be integrally (monolithically) formed. The sensor unit 100 formed by any of the methods may achieve the function effect described above.

While the example embodiment has been described above by using the sensor unit 100 including the one magnetic detection unit 10 as an example, the present example embodiment is also applicable to a case where a plurality of the magnetic detection units 10 are included and, in that case also, the same function effect as the function effect described above may be achieved. For example, the present example embodiment is applicable also to such cases where a plurality of magnetic detection units having the same magnetic sensing direction are included as the magnetic detection unit 10, where magnetic detection units having different magnetic sensing directions are included on a one-by-one basis, and where a plurality of each of magnetic detection units having different magnetic sensing directions are included. When the plurality of magnetic detection units are thus included and the signal processing circuits to be connected to the individual magnetic detection units are to be increased, as the signal processing circuits are increased, power consumption may be increased. As has been described above, the present example embodiment can reduce the power consumption, and therefore the present example embodiment can effectively be applied to the sensor unit 100 which includes the plurality of magnetic detection units and in which the power consumption may be increased.

The example embodiments described above are for the purpose of facilitating understanding of the technology, and are not to be interpreted as limiting the technology. Constituent elements of the example embodiments and arrangements, materials, conditions, shapes, sizes, and the like thereof are not limited to those shown by way of example, and can be changed as appropriate. In addition, components described in the different embodiments can partially be substituted or combined.

For example, the sensor unit 100 in the present example embodiment is applicable to a magnetic sensor unit and, when used as the magnetic sensor unit, the sensor unit 100 may also be used to sense a position change in the XY-plane or a position change in the Z-direction from a change in a magnetic field in the Z-direction. Examples of an application including the sensor not only include a strain gauge, an angle sensor, a position sensor, a compass, a current sensor, a switch, and the like, but also include electronic devices such as an actuator to be used for an articulating mechanism for a robot or the like, an open/close sensing mechanism of a notebook personal computer, a joystick, a brushless motor, and a magnetic encoder.

The following is a brief summary of specific aspects and effects of the present disclosure. A signal processing circuit according to an aspect of the present disclosure provides a signal processing circuit that processes a detection signal output from a sensor and including a direct-current component and an alternating-current component and includes: a low-pass filter that extracts the direct-current component from the detection signal; and a high-pass filter that extracts the alternating-current component from the detection signal.

The signal processing circuit according to the aspect of the present disclosure may also include: a signal addition unit that adds up the direct-current component extracted by the low-pass filter and the alternating-current component extracted by the high-pass filter.

The signal processing circuit according to the aspect of the present disclosure may also include: a signal correction unit that applies a correction value calculated on the basis of the direct-current component to an addition signal, which is an output signal from the signal addition unit, to correct the addition signal.

The signal processing circuit according to the aspect of the present disclosure may also include: a first signal processing unit that performs first signal processing on the direct-current component; and a second signal processing unit that performs second signal processing on the alternating-current component.

In the signal processing circuit according to the aspect of the present disclosure, it may also be possible that the sensor is a magnetic sensor.

A sensor unit according to the aspect of the present disclosure includes: a sensor; and a signal processing circuit which is formed integrally with the sensor.

According to each of the foregoing example embodiments, it is possible to provide a signal processing circuit capable of reducing power consumption.

1. A signal processing circuit that processes a detection signal, output from a sensor, and including a direct-current component and an alternating-current component, the signal processing circuit comprising:
a low-pass filter that extracts the direct-current component from the detection signal; and
a high-pass filter that extracts the alternating-current component from the detection signal.

2. The signal processing circuit according to claim 1, further comprising:
a signal addition unit that adds up the direct-current component extracted by the low-pass filter and the alternating-current component extracted by the high-pass filter.

3. The signal processing circuit according to claim 2, further comprising:
a signal correction unit that applies a correction value calculated on the basis of the direct-current component to an addition signal, which is an output signal from the signal addition unit, to correct the addition signal.

4. The signal processing circuit according to claim 1, further comprising:
a first signal processing unit that performs first signal processing on the direct-current component; and
a second signal processing unit that performs second signal processing on the alternating-current component.

5. The signal processing circuit according to claim 4, further comprising:
a signal addition unit that adds up a first output signal, which is an output signal from the first signal processing unit, and a second output signal, which is an output signal from the second signal processing unit.

6. The signal processing circuit according to claim 5, further comprising:
a signal correction unit that applies a correction value calculated on the basis of the direct-current component to an addition signal, which is an output signal from the signal addition unit, to correct the addition signal.

7. The signal processing circuit according to claim 1, wherein the sensor is a magnetic sensor.

8. A sensor unit comprising:
the sensor; and
the signal processing circuit according to claim 1, which is formed integrally with the sensor.
